(19) United States
(12) Patent Application Publication
(10) Pub. No.: US 2017/0212420 A1
(43) Pub. Date: Jul. 27, 2017

(54) LAYER STRUCTURE COMPRISING A PHOTOPOLYMER LAYER AND A SUBSTRATE LAYER

(71) Applicant: Covestro Deutschland AG, Leverkusen (DE)

(72) Inventors: THOMAS FÄECKE, Leverkusen (DE); Friedrich-Karl BRUDER, Krefeld (DE); Dennis HÕNEL, Zülpich-Wichterich (DE); Günther WALZE, Leverkusen (DE); Thoms RÖLLE, Leverkusen (DE)

(21) Appl. No.: 15/500,293

(22) PCT Filed: Jul. 31, 2015
(86) PCT No.: PCT/EP2015/067652

§ 371 Date: Jan. 30, 2017

(30) Foreign Application Priority Data
Aug. 1, 2014 (EP) 14179506.2

(51) Int. Cl. G03F 7/035; G03F 7/027

(52) U.S. Cl. CPC G03F 7/035; G03F 7/027

(57) ABSTRACT

The invention relates to layered setup comprising a substrate layer and a photopolymer layer bonded thereto at least segmentally, wherein the substrate layer has an average retardation of ≦60 nm.

The invention relates to a layered setup comprising a substrate layer and a photopolymer layer bonded thereto at least segmentally. The invention further relates to an optical display comprising a layered setup according to the invention.

Photopolymers are an important class of recording materials for volume holograms. In holographic exposure, the interference field of signal light beam and reference light beam (that of two planar waves in the simplest case) is mapped into a refractive index grating by the local photopolymerization of, for example, high-refractive acrylates at loci of high intensity in the interference field. It is the refractive index grating in the photopolymer which is the hologram and which contains all the information in the signal light beam. The signal wavefront is reconstructable by illuminating the hologram with the reference light beam alone. The strength of the signal thus reconstructed relative to the strength of the incident reference light is called the diffraction efficiency, DE in what follows.

Photopolymer layer thickness d is likewise important in that the smaller d is, the greater are the particular angle and light frequency acceptance widths. To produce bright and easily visible holograms, refractive index modulation Δn has to be high and thickness d has to be low while maximizing DE (P. Hariharan, Optical Holography, 2nd Edition, Cambridge University Press, 1996).

Volume holograms, as will be known, are not only useful for producing picture holograms with a 3D effect, they are likewise suitable for optical applications. There they act like an optical element whereby a wavefront is transformable into some other defined wavefront via diffractive optics. The ability to freely choose the operative angles for these optical elements in a very elegant way is advantageous. Transmission holograms can thus be used to achieve transmissive geometries (incoming wavefront on one side of the holographic medium, outgoing wavefront on the other). In reflection holograms, the incoming and outgoing wavefronts of the optical element are on the same side of the holographic medium, they thereby act akin to a mirror. There are further applications where one of the two wavefronts is situated in the holographic medium, or underneath in a light-guiding layer in optical contact therewith, while the other exits from the medium. These are known as edge-lit or waveguiding holograms.

In addition to the geometry of the holographically optical element, the wavefront transformation is freely choosable. This is accomplished by a corresponding signal and reference waveform being selected during holographic exposure.

Conceptionally, the wavefront transformation approach of employing holographically optical elements is extremely elegant, but in practice is also subject to corresponding requirements regarding optical quality. While the familiar 3D picture holograms enthuse the observer with their presentation of spatial depth, specific imaging qualities of the optics are relevant in optical applications. Optical elements of this type are useful in demanding applications such as spectroscopy or astronomy. They are likewise suitable for use in electronic displays, for example in 3D displays. Particularly in relation to imaging optics, in optical measuring instruments or in applications with zero error tolerance (e.g., in relation to pixel errors in electronic displays, in CCD cameras or else in precision tools), the photopolymers used as a recording material have to meet these particularly high requirements.

One criterion for assessing the quality of optical instruments is the Strehl ratio, or the “Strehl” for short, which represents the ratio of experimentally maximum intensity of a point light source in the image plane of an optical system to the theoretical maximum intensity of the same “perfect” optical system.

A further criterion for assessing optical quality is the root mean square (RMS) deviation, i.e., the first derivative of the phase profile with respect to distance along a line. The value should be very small for a high level of optical quality.

The overall quality of a layered setup is quantifiable from the quotient formed by dividing the derivative of the RMS value into Strehl. This quotient thereby corresponds to the lateral length of the surface for a phase change of one wavelength and is hereinafter referred to as the phase shift range length P.

$$P = \frac{Strehl}{\frac{d RMS}{dx}}$$

The phase shift range length P needs to be at least 0.8 cm/wavelength for good optics, at least 1.0 cm/wavelength for very good optics and at least 1.2 cm/wavelength for excellent optics.

The problem addressed by the present invention was that of providing a layered setup which is of the type referred to at the beginning and which is useful as recording medium for high grade holographically optical elements, achieving optical qualities as possessed by a phase shift range length P of at least 0.8 cm/wavelength, preferably 1.0 cm/wavelength and more preferably 1.2 cm/wavelength.

The problem is solved by a layered setup comprising a substrate layer and a photopolymer layer bonded thereto at least segmentally, wherein the substrate layer has an average retardation of ≦560 nm.

It was found that, surprisingly, layered setups comprising a substrate layer which have the retardation provided according to the invention have a high level of optical quality. This makes it possible, for example, to expose high-grade holographically optical elements into the photopolymer layer of the layered setup.

In a first embodiment, the substrate layer may have an average retardation of ≦40 nm and preferably of ≦30 nm. In this case, the layered setups are useful for optical applications of particularly high quality.

The average retardation of the substrate layer is quantifiable by an imaging polarimeter system comprising a monochromatic LED light source, a polarizer, a sample, a lambda quarter plate, an analyser and a detector, being used to measure the polarization plane rotation α in a positionally resolved manner and the positionally resolved retardation R being computed by the formula R=α*λ/180°, where λ is the measuring frequency, and then being arithmetically averaged over all positionally resolved retardation values. The LED light source has a narrow-banded emission spectrum having a full width at half maximum value <50 nm and also a maximum emission wavelength of λ=580 nm to 595 nm.

In the measurement, the linearly polarized monochromatic LED light of the light source is transformed by the substrate layer into elliptically polarized light and then by the lambda quarter plate back into linearly polarized light having a possibly different polarization plane direction by the angle α. This angle is then quantifiable in a positionally resolved manner by means of the analyser and the detector. The retardation R can subsequently be computed by means of the relationship

$$R = \frac{a \cdot λ}{180 °}$$

in nanometres [nm]. For a given position of the substrate layer, the highest light intensity is obtained at a certain angle α and then gives the retardation for this location.

Owing to the measurement principle involving a certain measuring axis arrangement for the polarization plane of the lighter, the measurement is then repeated from other polarization planes. Typically, the polarizer is turned in 90° steps and the measurement repeated each time. The retardation data are then averaged from the positionally based measurements to thereby obtain the final result of the positionally dependent measurement for each position.

Positionally dependent refers to the retardation measured on the substrate layer in a positionally accurate manner by the detector system in the polarimeter system. The area of measurement is from 4 mm² to 0.01 mm² in size, preferably from 0.5 mm² to 0.02 mm² in size.

After measurement, the maximum and the average retardations are determined across the full area of measurement. In a further preferred embodiment, the substrate layer has a maximum (positionally resolved) retardation of ≦200 nm, preferably of ≦100 nm and more preferably of ≦50 nm.

In a likewise preferred embodiment, the photopolymer layer comprises matrix polymers, writing monomers and a photoinitiator system.

Matrix polymers used may be amorphous thermoplastics, for example polyacrylates, polymethylmethacrylates or copolymers of methyl methacrylate, methacrylic acid or other alkyl acrylates and alkyl methacrylates, and also acrylic acid, for example polybutyl acrylate, and also polyvinyl acetate and polyvinyl butyrate, the partially hydrolysed derivatives thereof, such as polyvinyl alcohols, and copolymers with ethylenes and/or further (meth)acrylates, gelatins, cellulose esters and cellulose ethers such as methyl cellulose, cellulose acetobutyrate, silicones, for example polydimethylsilicone, polyurethanes, polybutadienes and polyisoprenes, and also polyethylene oxides, epoxy resins, especially aliphatic epoxy resins, polyamides, polycarbonates and the systems cited in U.S. Pat. No. 4,994,347A and therein.

The matrix polymers may be particularly in a crosslinked state and more preferably in a three-dimensionally crosslinked state.

The matrix polymers more preferably comprise or consist of polyurethanes and most preferably comprise or consist of three-dimensionally crosslinked polyurethanes.

Such crosslinked-polyurethane matrix polymers are obtainable for example by reaction of at least one polyisocyanate component a) with at least one isocyanate-reactive component b).

The polyisocyanate component a) comprises at least one organic compound having at least two NCO groups. These organic compounds may especially be monomeric di- and triisocyanates, polyisocyanates and/or NCO-functional prepolymers. The polyisocyanate component a) may also contain or consist of mixtures of monomeric di- and triisocyanates, polyisocyanates and/or NCO-functional prepolymers.

Monomeric di- and triisocyanates used may be any of the compounds that are well known per se to those skilled in the art, or mixtures thereof. These compounds may have aromatic, araliphatic, aliphatic or cycloaliphatic structures. The monomeric di- and triisocyanates may also comprise minor amounts of monoisocyanates, i.e. organic compounds having one NCO group.

Examples of suitable monomeric di- and triisocyanates are butane 1,4-diisocyanate, pentane 1,5-diisocyanate, hexane 1,6-diisocyanate (hexamethylene diisocyanate, HDI), 2,2,4-trimethylhexamethylene diisocyanate and/or 2,4,4-trimethylhexamethylene diisocyanate (TMDI), isophorone diisocyanate (IPDI), 1,8-diisocyanato-4-(isocyanatomethyl)octane, bis(4,4′-isocyanatocyclohexyl)methane and/or bis(2′,4-isocyanatocyclohexyl)methane and/or mixtures thereof having any isomer content, cyclohexane 1,4-diisocyanate, the isomeric bis(isocyanatomethyl)cyclohexanes, 2,4- and/or 2,6-diisocyanato-1-methylcyclohexane (hexahydrotolylene 2,4- and/or 2,6-diisocyanate, H-TDI), phenylene 1,4-diisocyanate, tolylene 2,4- and/or 2,6-diisocyanate (TDI), naphthylene 1,5-diisocyanate (NDI), diphenylmethane 2,4′- and/or 4,4′-diisocyanate (MDI), 1,3-bis(isocyanatomethyl)benzene (XDI) and/or the analogous 1,4 isomers or any desired mixtures of the aforementioned compounds.

Suitable polyisocyanates are compounds which have urethane, urea, carbodiimide, acylurea, amide, isocyanurate, allophanate, biuret, oxadiazinetrione, uretdione and/or iminooxadiazinedione structures and are obtainable from the aforementioned di- or triisocyanates.

More preferably, the polyisocyanates are oligomerized aliphatic and/or cycloaliphatic di- or triisocyanates, it being possible to use especially the above aliphatic and/or cycloaliphatic di- or triisocyanates.

Very particular preference is given to polyisocyanates having isocyanurate, uretdione and/or iminooxadiazinedione structures, and biurets based on HDI or mixtures thereof.

Suitable prepolymers contain urethane and/or urea groups, and optionally further structures formed through modification of NCO groups as specified above. Prepolymers of this kind are obtainable, for example, by reaction of the abovementioned monomeric di- and triisocyanates and/or polyisocyanates a1) with isocyanate-reactive compounds b1).

Isocyanate-reactive compounds b1) used may be alcohols, amino or mercapto compounds, preferably alcohols. These may especially be polyols. Most preferably, isocyanate-reactive compounds b1) used may be polyester polyols, polyether polyols, polycarbonate polyols, poly(meth)acrylate polyols and/or polyurethane polyols.

Suitable polyester polyols are, for example, linear polyester diols or branched polyester polyols, which can be obtained in a known manner by reaction of aliphatic, cycloaliphatic or aromatic di- or polycarboxylic acids or anhydrides thereof with polyhydric alcohols of OH functionality ≧2. Examples of suitable di- or polycarboxylic acids are polybasic carboxylic acids such as succinic acid, adipic acid, suberic acid, sebacic acid, decanedicarboxylic acid, phthalic acid, terephthalic acid, isophthalic acid, tetrahydrophthalic acid or trimellitic acid, and acid anhydrides such as phthalic anhydride, trimellitic anhydride or succinic anhydride, or any desired mixtures thereof. The polyester polyols may also be based on natural raw materials such as castor oil. It is likewise possible that the polyester polyols are based on homo- or copolymers of lactones, which can preferably be obtained by addition of lactones or lactone mixtures, such as butyrolactone, ε-caprolactone and/or methyl-ε-caprolactone onto hydroxy-functional compounds such as polyhydric alcohols of OH functionality ≧2, for example of the abovementioned type.

Examples of suitable alcohols are all polyhydric alcohols, for example the C₂-C₁₂ diols, the isomeric cyclohexanediols, glycerol or any desired mixtures thereof.

Suitable polycarbonate polyols are obtainable in a manner known per se by reaction of organic carbonates or phosgene with diols or diol mixtures.

Suitable organic carbonates are dimethyl, diethyl and diphenyl carbonate.

Suitable diols or mixtures comprise the polyhydric alcohols of OH functionality ≧2 mentioned per se in the context of the polyester segments, preferably butane-1,4-diol, hexane-1,6-diol and/or 3-methylpentanediol. It is also possible to convert polyester polyols to polycarbonate polyols.

Suitable polyether polyols are polyaddition products, optionally of blockwise structure, of cyclic ethers onto OH- or NH-functional starter molecules.

Suitable cyclic ethers are, for example, styrene oxides, ethylene oxide, propylene oxide, tetrahydrofuran, butylene oxide, epichlorohydrin, and any desired mixtures thereof.

Starters used may be the polyhydric alcohols of OH functionality ≧2 mentioned per se in the context of the polyester polyols, and also primary or secondary amines and amino alcohols.

Preferred polyether polyols are those of the aforementioned type based exclusively on propylene oxide, or random or block copolymers based on propylene oxide with further 1-alkylene oxides. Particular preference is given to propylene oxide homopolymers and random or block copolymers containing oxyethylene, oxypropylene and/or oxybutylene units, where the proportion of the oxypropylene units based on the total amount of all the oxyethylene, oxypropylene and oxybutylene units amounts to at least 20% by weight, preferably at least 45% by weight. Oxypropylene and oxybutylene here encompasses all the respective linear and branched C₃ and C₄ isomers.

Additionally suitable as constituents of the polyol component b1), as polyfunctional, isocyanate-reactive compounds, are also low molecular weight (i.e. with molecular weights ≦500 g/mol), short-chain (i.e. containing 2 to 20 carbon atoms), aliphatic, araliphatic or cycloaliphatic di-, tri- or polyfunctional alcohols.

These may, for example, in addition to the abovementioned compounds, be neopentyl glycol, 2-ethyl-2-butylpropanediol, trimethylpentanediol, positionally isomeric diethyloctanediols, cyclohexanediol, 1,4-cyclohexanedimethanol, 1,6-hexanediol, 1,2- and 1,4-cyclohexanediol, hydrogenated bisphenol A, 2,2-bis(4-hydroxycyclohexyl)propane or 2,2-dimethyl-3-hydroxypropionic acid, 2,2-dimethyl-3-hydroxypropionate. Examples of suitable triols are trimethylolethane, trimethylolpropane or glycerol. Suitable higher-functionality alcohols are di(trimethylolpropane), pentaerythritol, dipentaerythritol or sorbitol.

It is especially preferable when the polyol component is a difunctional polyether, polyester, or a polyether-polyester block copolyester or a polyether-polyester block copolymer having primary OH functions.

It is likewise possible to use amines as isocyanate-reactive compounds b1). Examples of suitable amines are ethylenediamine, propylenediamine, diaminocyclohexane, 4,4′-dicyclohexylmethanediamine, isophoronediamine (IPDA), difunctional polyamines, for example the Jeffamines®, amine-terminated polymers, especially having number-average molar masses ≦10 000 g/mol. Mixtures of the aforementioned amines can likewise be used.

It is likewise possible to use amino alcohols as isocyanate-reactive compounds b1). Examples of suitable amino alcohols are the isomeric aminoethanols, the isomeric aminopropanols, the isomeric aminobutanols and the isomeric aminohexanols, or any desired mixtures thereof.

All the aforementioned isocyanate-reactive compounds b1) can be mixed with one another as desired.

It is also preferable when the isocyanate-reactive compounds b1) have a number-average molar mass of ≧200 and ≦10 000 g/mol, further preferably ≧500 and ≦8000 g/mol and most preferably ≧800 and ≦5000 g/mol. The OH functionality of the polyols is preferably 1.5 to 6.0, more preferably 1.8 to 4.0.

The prepolymers of the polyisocyanate component a) may especially have a residual content of free monomeric di- and triisocyanates of <1% by weight, more preferably <0.5% by weight and most preferably <0.3% by weight.

It is optionally also possible that the polyisocyanate component a) contains, entirely or in part, organic compound whose NCO groups have been fully or partly reacted with blocking agents known from coating technology. Example of blocking agents are alcohols, lactams, oximes, malonic esters, pyrazoles, and amines, for example butanone oxime, diisopropylamine, diethyl malonate, ethyl acetoacetate, 3,5-dimethylpyrazole, ε-caprolactam, or mixtures thereof.

It is especially preferable when the polyisocyanate component a) comprises compounds having aliphatically bonded NCO groups, aliphatically bonded NCO groups being understood to mean those groups that are bonded to a primary carbon atom.

The isocyanate-reactive component b) preferably comprises at least one organic compound having an average of at least 1.5 and preferably 2 to 3 isocyanate-reactive groups. In the context of the present invention, isocyanate-reactive groups are regarded as being preferably hydroxyl, amino or mercapto groups.

The isocyanate-reactive component may especially comprise compounds having a numerical average of at least 1.5 and preferably 2 to 3 isocyanate-reactive groups.

Suitable polyfunctional isocyanate-reactive compounds of component b) are for example the above-described compounds b1).

The writing monomers may be compounds capable of photoinitiated polymerization. These are cationically and anionically polymerizable and also free-radically polymerizable compounds. Particular preference is given to free-radically polymerizable compounds. Examples of suitable classes of compounds are unsaturated compounds such as (meth)acrylates, α,β-unsaturated carboxylic acid derivatives such as, for example, maleates, fumarates, maleimides, acrylamides, and also vinyl ethers, propenyl ethers, allyl ethers and compounds containing dicyclopentadienyl units, and also olefinically unsaturated compounds, for example styrene, α-methylstyrene, vinyltoluene and/or olefins, comprises or consists of. It is further also possible for thioene reactive compounds, e.g. thiols and activated double bonds, to be free-radically polymerized.

Examples of (meth)acrylates usable with preference are phenyl acrylate, phenyl methacrylate, phenoxyethyl acrylate, phenoxyethyl methacrylate, phenoxyethoxyethyl acrylate, phenoxyethoxyethyl methacrylate, phenylthioethyl acrylate, phenylthioethyl methacrylate, 2-naphthyl acrylate, 2-naphthyl methacrylate, 1,4-bis(2-thionaphthyl)-2-butyl acrylate, 1,4-bis(2-thionaphthyl)-2-butyl methacrylate, bisphenol A diacrylate, bisphenol A dimethacrylate, and the ethoxylated analogue compounds thereof, N-carbazolyl acrylates.

Urethane (meth)acrylates are also usable as writing monomers with particular preference.

It is very particularly preferable for the writing monomers to comprise or consist of one or more urethane (meth)acrylates.

Urethane (meth)acrylates herein are compounds having at least one acrylic ester or methacrylic acid group as well as at least one urethane bond. Compounds of this kind can be obtained, for example, by reacting a hydroxy-functional acrylate or (meth)acrylate with an isocyanate-functional compound.

Examples of isocyanate-functional compounds usable for this purpose are monoisocyanates, and the monomeric diisocyanates, triisocyanates and/or polyisocyanates mentioned under a). Examples of suitable monoisocyanates are phenyl isocyanate, the isomeric methylthiophenyl isocyanates. Di-, tri- or polyisocyanates have been mentioned above, and also triphenylmethane 4,4′,4″-triisocyanate and tris(p-isocyanatophenyl) thiophosphate or derivatives thereof with urethane, urea, carbodiimide, acylurea, isocyanurate, allophanate, biuret, oxadiazinetrione, uretdione, iminooxadiazinedione structure and mixtures thereof. Preference is given to aromatic di-, tri- or polyisocyanates.

Useful hydroxy-functional acrylates or methacrylates for the preparation of urethane acrylates include, for example, compounds such as 2-hydroxyethyl (meth)acrylate, polyethylene oxide mono(meth)acrylates, polypropylene oxide mono(meth)acrylates, polyalkylene oxide mono(meth)acrylates, poly(ε-caprolactone) mono(meth)acrylates, for example Tone® M100 (Dow, Schwalbach, Del.), 2-hydroxypropyl (meth)acrylate, 4-hydroxybutyl (meth)acrylate, 3-hydroxy-2,2-dimethylpropyl (meth)acrylate, hydroxypropyl (meth)acrylate, 2-hydroxy-3-phenoxypropyl acrylate, the hydroxy-functional mono-, di- or tetraacrylates of polyhydric alcohols such as trimethylolpropane, glycerol, pentaerythritol, dipentaerythritol, ethoxylated, propoxylated or alkoxylated trimethylolpropane, glycerol, pentaerythritol, dipentaerythritol or the technical mixtures thereof. Preference is given to 2-hydroxyethyl acrylate, hydroxypropyl acrylate, 4-hydroxybutyl acrylate and poly(ε-caprolactone) mono(meth)acrylate.

It is likewise possible to use the fundamentally known hydroxyl-containing epoxy (meth)acrylates having OH contents of 20 to 300 mg KOH/g or hydroxyl-containing polyurethane (meth)acrylates having OH contents of 20 to 300 mg KOH/g or acrylated polyacrylates having OH contents of 20 to 300 mg KOH/g and mixtures thereof, and mixtures with hydroxyl-containing unsaturated polyesters and mixtures with polyester (meth)acrylates or mixtures of hydroxyl-containing unsaturated polyesters with polyester (meth)acrylates.

Preference is given especially to urethane (meth)acrylates obtainable from the reaction of tris(p-isocyanatophenyl) thiophosphate and/or m-methylthiophenyl isocyanate with alcohol-functional acrylates such as hydroxyethyl (meth)acrylate, hydroxypropyl (meth)acrylate and/or hydroxybutyl (meth)acrylate.

It is also preferable for compounds to be used as writing monomers that have two or more free-radically polymerizable groups per molecule (multifunctional writing monomers). These are usable alone or in combination with writing monomers having just one free-radically polymerizable group per molecule.

Preferably, therefore, the writing monomers may comprise or consist of at least one mono- and/or one multifunctional (meth)acrylate writing monomer. More preferably, the writing monomers may comprise or consist of at least one mono- and/or one multifunctional urethane (meth)acrylate. It is very particularly preferable for the writing monomers to comprise or consist of at least one monofunctional urethane (meth)acrylate and at least one multifunctional urethane (meth)acrylate.

Suitable (meth)acrylate writing monomers are especially compounds of general formula (I)

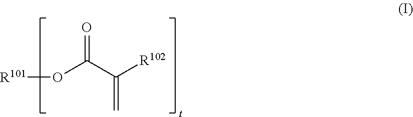

where t is ≧1 and ≦4 and R¹⁰¹ is a linear, branched, cyclic or heterocyclic unsubstituted or else optionally heteroatom-substituted organic moiety and/or R¹⁰² is hydrogen, a linear, branched, cyclic or heterocyclic unsubstituted or else optionally heteroatom-substituted organic moiety. More preferably, R¹⁰² is hydrogen or methyl and/or R¹⁰¹ is a linear, branched, cyclic or heterocyclic organic moiety which is unsubstituted or else optionally substituted with heteroatoms.

The photoinitiator system comprises at least one photoinitiator.

Photoinitiators are compounds activatable typically by means of actinic radiation, which can trigger polymerization of the writing monomers. In the case of the photoinitiators, a distinction can be made between unimolecular (type I) and bimolecular (type II) initiators. In addition, they are distinguished by their chemical nature as photoinitiators for free-radical, anionic, cationic or mixed types of polymerization.

Type I photoinitiators (Norrish type I) for free-radical photopolymerization form free radicals on irradiation through unimolecular bond scission. Examples of type I photoinitiators are triazines, oximes, benzoin ethers, benzil ketals, bisimidazoles, aroylphosphine oxides, sulphonium salts and iodonium salts.

Type II photoinitiators (Norrish type II) for free-radical polymerization consist of a dye as sensitizer and a coinitiator, and undergo a bimolecular reaction on irradiation with light matched to the dye. First of all, the dye absorbs a photon and transfers energy from an excited state to the coinitiator. The latter releases the polymerization-triggering free radicals through electron or proton transfer or direct hydrogen abstraction.

In the context of this invention, preference is given to using type II photoinitiators. Therefore, in one preferred embodiment, the photoinitiator system consists of a sensitizer that absorbs in the visible spectrum and of a co-initiator, wherein the co-initiator may preferably be a borate co-initiator.

Photoinitiator systems of this kind are described in principle in EP 0 223 587 A and consist preferably of a mixture of one or more dyes with ammonium alkylarylborate(s).

Suitable dyes which, together with an ammonium alkylarylborate, form a type II photoinitiator are the cationic dyes described in WO 2012062655, in combination with the anions likewise described therein.

Cationic dyes are preferably understood to mean those from the following classes: acridine dyes, xanthene dyes, thioxanthene dyes, phenazine dyes, phenoxazine dyes, phenothiazine dyes, tri(het)arylmethane dyes—especially diamino- and triamino(het)arylmethane dyes, mono-, di-, tri- and pentamethinecyanine dyes, hemicyanine dyes, externally cationic merocyanine dyes, externally cationic neutrocyanine dyes, zeromethine dyes—especially naphtholactam dyes, streptocyanine dyes. Dyes of this kind are described, for example, in H. Berneth in Ullmann's Encyclopedia of Industrial Chemistry, Azine Dyes, Wiley-VCH Verlag, 2008, H. Berneth in Ullmann's Encyclopedia of Industrial Chemistry, Methine Dyes and Pigments, Wiley-VCH Verlag, 2008, T. Gessner, U. Mayer in Ullmann's Encyclopedia of Industrial Chemistry, Triarylmethane and Diarylmethane Dyes, Wiley-VCH Verlag, 2000.

Particular preference is given to phenazine dyes, phenoxazine dyes, phenothiazine dyes, tri(het)arylmethane dyes—especially diamino- and triamino(het)arylmethane dyes, mono-, di-, tri- and pentamethinecyanine dyes, hemicyanine dyes, zeromethine dyes—especially naphtholactam dyes, streptocyanine dyes.

Examples of cationic dyes are Astrazon Orange G, Basic Blue 3, Basic Orange 22, Basic Red 13, Basic Violet 7, Methylene Blue, New Methylene Blue, Azure A, 2,4-diphenyl-6-(4-methoxyphenyl)pyrylium, Safranin O, Astraphloxin, Brilliant Green, Crystal Violet, Ethyl Violet and thionine.

Preferred anions are especially C₈- to C₂₅-alkanesulphonate, preferably C₁₃- to C₂₅-alkanesulphonate, C₃- to C₁₈-perfluoroalkanesulphonate, C₄- to C₁₈-perfluoroalkanesulphonate bearing at least 3 hydrogen atoms in the alkyl chain, C9- to C₂₅-alkanoate, C9- to C₂₅-alkenoate, C₈- to C₂₅-alkylsulphate, preferably C₁₃- to C₂₅-alkylsulphate, C₈ to C₂₅-alkenylsulphate, preferably C₁₃- to C₂₅-alkenylsulphate, C₃- to C₁₈-perfluoroalkylsulphate, C₄- to C₁₈-perfluoroalkylsulphate bearing at least 3 hydrogen atoms in the alkyl chain, polyether sulphates based on at least 4 equivalents of ethylene oxide and/or 4 equivalents of propylene oxide, bis(C₄- to C₂₅-alkyl, C₅- to C₇-cycloalkyl, C₃- to C₈-alkenyl or C₇- to C₁₁-aralkyl)sulphosuccinate, bis-C₂ to C₁₀-alkylsulphosuccinate substituted by at least 8 fluorine atoms, C₈- to C₂₅-alkylsulphoacetates, benzenesulphonate substituted by at least one radical from the group of halogen, C₄- to C₂₅-alkyl, perfluoro-C₁- to C₈-alkyl and/or C₁- to C₁₂-alkoxycarbonyl, naphthalene- or biphenylsulphonate optionally substituted by nitro, cyano, hydroxyl, C₁- to C₂₅-alkyl, C₁- to C₁₂-alkoxy, amino, C₁- to C₁₂-alkoxycarbonyl or chlorine, benzene-, naphthalene- or biphenyldisulphonate optionally substituted by nitro, cyano, hydroxyl, C₁- to C₂₅-alkyl, C₁- to C₁₂-alkoxy, C₁- to C₁₂-alkoxycarbonyl or chlorine, benzoate substituted by dinitro, C₆- to C₂₅-alkyl, C₄- to C₁₂-alkoxycarbonyl, benzoyl, chlorobenzoyl or tolyl, the anion of naphthalenedicarboxylic acid, diphenyl ether disulphonate, sulphonated or sulphated, optionally at least monounsaturated C₈ to C₂₅ fatty acid esters of aliphatic C₁ to C₈ alcohols or glycerol, bis(sulpho-C₂- to C₆-alkyl) C₃- to C₁₂-alkanedicarboxylates, bis(sulpho-C₂- to C₆-alkyl) itaconates, (sulpho-C₂- to C₆-alkyl) C₆- to C₁₈-alkanecarboxylates, (sulpho-C₂- to C₆-alkyl) acrylates or methacrylates, triscatechol phosphate optionally substituted by up to 12 halogen radicals, an anion from the group of tetraphenylborate, cyanotriphenylborate, tetraphenoxyborate, C₄- to C₁₂-alkyltriphenylborate, wherein the phenyl or phenoxy radicals may be substituted by halogen, C₁- to C₄-alkyl and/or C₁- to C₄-alkoxy, C₄- to C₁₂-alkyltrinaphthylborate, tetra-C₁- to C₂₀-alkoxyborate, 7,8- or 7,9-dicarba-nido-undecaborate(1-) or (2-), which are optionally substituted on the boron and/or carbon atoms by one or two C₁- to C₁₂-alkyl or phenyl groups, dodecahydrodicarbadodecaborate(2-) or B—C₁- to C₁₂-alkyl-C-phenyldodecahydrodicarbadodecaborate(1-), where, in the case of polyvalent anions such as naphthalenedisulphonate, A⁻ represents one equivalent of this anion, and where the alkane and alkyl groups may be branched and/or may be substituted by halogen, cyano, methoxy, ethoxy, methoxycarbonyl or ethoxycarbonyl.

It is also preferable when the anion A⁻ of the dye has an AC log P in the range from 1 to 30, more preferably in the range from 1 to 12 and especially preferably in the range from 1 to 6.5. AC log P is computed after J. Comput. Aid. molluscicides Des. 2005, 19, 453; Virtual Computational Chemistry Laboratory, http://www.vcclab.org.

Suitable ammonium alkylarylborates are, for example (Cunningham et al., RadTech'98 North America UV/EB Conference Proceedings, Chicago, Apr. 19-22, 1998): tetrabutylammonium triphenylhexylborate, tetrabutylammonium triphenylbutylborate, tetrabutylammonium trinaphthylhexylborate, tetrabutylammonium tris(4-tert-butyl)phenylbutylborate, tetrabutylammonium tris(3-fluorophenyl)hexylborate hexylborate ([191726-69-9], CGI 7460, product from BASF SE, Basle, Switzerland), 1-methyl-3-octylimidazolium dipentyldiphenylborate and tetrabutylammonium tris(3-chloro-4-methylphenyl)hexylborate ([1147315-11-4], CGI 909, product from BASF SE, Basle, Switzerland).

The photoinitiator system may also contain mixtures of photoinitiators. According to the radiation source used, photoinitiator type and concentration is adaptable in a manner known to a person skilled in the art. Further details are described, for example, in P. K. T. Oldring (Ed.), Chemistry & Technology of UV & EB Formulations For Coatings, Inks & Paints, Vol. 3, 1991, SITA Technology, London, p. 61-328.

It is most preferable when the photoinitiator system comprises a combination of dyes whose absorption spectra at least partly cover the spectral range from 400 to 800 nm, with at least one coinitiator matched to the dyes.

It is also preferable when at least one photoinitiator suitable for a laser light colour selected from blue, green and red is present in the photoinitiator system.

It is also further preferable when the photoinitiator system contains one suitable photoinitiator each for at least two laser light colours selected from blue, green and red.

Finally, it is most preferable when the photoinitiator system contains one suitable photoinitiator for each of the laser light colours blue, green and red.

In a further preferred embodiment, the photopolymer layer comprises fluorourethanes, wherein these may preferably be compounds conforming to formula (II)

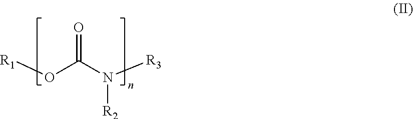

where n is ≧1 and ≦8 and R₁, R₂, R₃ are each independently hydrogen or linear, branched, cyclic or heterocyclic unsubstituted or else optionally heteroatom-substituted organic moieties, wherein at least one of R₁, R₂, R₃ is substituted with at least one fluorine atom and more preferably R₁ is an organic moiety having at least one fluorine atom.

The photopolymer layer may additionally also contain one or more free-radical stabilizers.

Useful free-radical stabilizers include, for example, the compounds described in “Methoden der organischen Chemie” (Houben-Weyl), 4th edition, Volume XIV/1, p. 433ff, Georg Thieme Verlag, Stuttgart 1961. Suitable classes of chemistries include, for example, those of phenols, cresoles, p-methoxyphenols, p-alkoxyphenols, hydroquinones, benzyl alcohols such as, for example, benzhydrol, quinones such as, for example, 2,5-di-tert-butylquinone, aromatic amines such as diisopropylamine or phenothiazine and also HALS amines.

Useful phenolic stabilizers include for example:

ortho-t.butylphenols such as, for example, ethylene bis[3,3-bis(3-tert-butyl-4-hydroxyphenyl)butyrate]; 1,1,3-tris(2′-methyl-4′-hydroxy-5′-tert-butylphenyl)butane; 1,3,5-tris(4-tert-butyl-3-hydroxy-2,6-dimethylbenzyl)-1,3,5-triazine-2,4,6-(1H,5H)-trione; bis-ortho.t.butylphenols such as, for example, 2,6-di-tert-butyl-4-methylphenol, esters of mono-, di-, tri-, tetra-, penta- and hexavalent alcohols with 3,5-di-tert-butyl-4-hydroxyphenylpropionic acid, e.g. with pentaerythrol as pentaerythritol tetrakis(3-(3,5-di-tert-butyl-4-hydroxyphenyl)propionate), with octyl alcohol such as octadecyl 3-(3,5-di-tert-butyl-4-hydroxyphenyl)propionate and the like;
phenolic oligomers having Bis-ortho-tert-butyl-phenol groups such as, for example, 1,3,5-trimethyl-2,4,6-tris(3,5-di-tert-butyl-4-hydroxybenzyl)benzene; tris(3,5-di-tert-butyl-4-hydroxybenzyl) isocyanurate, triethylene glycol bis[3-(3-tert.butyl-4-hydroxy-5-methylphenyl)propionate]; N,N′-hexamethylenebis[3-(3,5-di-tert.butyl-4-hydroxyphenyl)propionamide; 2,2′-methylenebis[4-methyl-6-(l-methylcyclohexyl)phenol]; sterically hindered phenols, e.g. 2,2′-ethylidenebis[4,6-di-tert.butylphenol], 2,2′-methylenebis(6-tert.butyl-4-methylphenol), 4,4′-butylidenebis(2-tert.butyl-5-methylphenol), 2,2′-isobutylidenebis(4,6-dimethylphenol) and other sterically hindered phenols, e.g. C7-9 branched alkyl esters of 3,5-bis(1,1-dimethylethyl)-4-hydroxyphenylpropanoic acid.

Useful sterically hindered amines (i.e. HALS amines) include for example:

2,2,6,6-tetramethyl-4-piperidinyl octadecanoate; 1-methyl-10-(1,2,2,6,6-pentamethyl-4-piperidinyl) decanedioate; 3-dodecyl-1-(2,2,6,6-tetramethyl-4-piperidinyl) 2,5-pyrrolidinedione; N,N′-bisformyl-N,N′-bis-(2,2,6,6-tetramethyl-4-piperidinyl) hexamethylenediamine; bis-(2,2,6,6-tetramethyl-4-piperidyl) sebacate; 1,10-bis(1,2,2,6,6-pentamethyl-4-piperidinyl) decanedioate; 1,3:2,4-bis-O-(2,2,6,6-tetramethyl-4-piperidinylidene)-D-glucitol; 1,1′-(1,2-ethanediyl)bis[3,3,5,5-tetramethyl-2-piperazinone]; poly[[6-[(1,1,3,3-tetramethylbutyl) amino]-s-triazine-2,4-diyl]-[(2,2,6,6-tetramethyl-4-piperidyl)imino]hexamethylene-[(2,2,6,6-tetramethyl-4-piperidyl)imino; poly([6-(4-morpholinyl)-1,3,5-triazine-2,4-diyl][(2,2,6,6-tetramethyl-4-piperidinyl)imino]-1,6-hexanediyl[(2,2,6,6-tetramethyl-4-piperidinyl)imino]]; 2,2,4,4-tetramethyl-20-(2-oxiranylmethyl)-7-oxa-3,20-diazadispiro[5.1.11.2]heneicosan-21-one; 1,1′,1″-[1,3,5-triazine-2,4,6-triyltris[(cyclohexylimino)-2, 1-ethanediyl]]tris[3,3,5,5-tetramethyl-piperazinone; homo- and copolymers of N-(2,2,6,6-tetramethyl-4-piperidinyl)maleinimide with terminal olefins and/or alkyl acrylates; (poly)esters of 4-hydroxy-2,2,6,6-tetramethyl-1-piperidineethanol with carboxylic acids, including in particular with dicarboxylic acids to form polymers such as, for example, poly(4-hydroxy-2,2,6,6-tetramethyl-1-piperidineethanol-alt-1,4-butane diacid);
N-alkyl-substituted sterically hindered amines such as, for example, 3-dodecyl-1-(1,2,2,6,6-pentamethyl-4-piperidinyl)-2,5-pyrrolidinedione; bis(1,2,2,6,6-pentamethyl-4-piperidyl) sebacate; methyl-(1,2,2,6,6-pentamethyl-4-piperidyl) sebacate; 1-(methyl)-8-(1,2,2,6,6-pentamethyl-4-piperidinyl) sebacate; 1,10-bis(1,2,2,6,6-pentamethyl-4-piperidinyl) decanedioate; 1,1′,1″-[1,3,5-triazine-2,4,6-triyltris[(cyclohexylimino)-2,1-ethanediyl]]tris[3,3,4,5,5-pentamethyl-2-piperazinone;
N-oxyl-substituted sterically hindered amines such as, for example, bis(1-oxyl-2,2,6,6,tetramethylpiperidin-4-yl) sebacate;
alkoxy-substituted sterically hindered amines such as, for example, 1,10-bis(1-octyloxy-2,2,6,6-tetramethyl-4-piperidinyl) decanedioate;
acetyl-substituted sterically hindered amines such as, for example, 1N-(1-acetyl-2,2,6,6-tetramethyl-4-piperidinyl)-2N-dodecyl-ethanediamide;

Selectively unsubstituted, N-alkyl-substituted, N-acyl-substituted, N-oxyl-substituted sterically hindered amines combined with phenolic stabilizer groups in one molecule, e.g. bis(1,2,2,6,6-pentamethyl-4-piperidyl) [[3,5-bis(1,1-dimethylethyl)-4-hydroxyphenyl]methyl]butylmalonate.

Preferred free-radical stabilizers are 2,6-di-tert-butyl-4-methylphenol, p-methoxyphenol, 1,10-bis(1,2,2,6,6-pentamethyl-4-piperidinyl) decanedioate; 1-methyl 10-(1,2,2,6,6-pentamethyl-4-piperidinyl) decanedioate.

It is particularly preferable for the photopolymer layer to contain two or more different stabilizers such as, for example, one phenolic stabilizer and one sterically hindered amine.

It is likewise particularly preferable for the photopolymer layer to contain from 0.001 to 2 wt %, more preferably from 0.001 to 1.5 and yet more preferably from 0.01 to 1.0 wt % of one or more, but preferably two or more, free-radical stabilizers.

The photopolymer layer may optionally also contain one or more catalysts. Catalysts to speed urethane formation may be concerned here in particular. Examples thereof are tin octoate, zinc octoate, butyltin trisoctoate, dibutyltin dilaurate, dimethylbis[(1-oxoneodecyl)oxy]stannane, dimethyltin dicarboxylate, zirconium bis(ethylhexanoate), zirconium acteylacetonate or tertiary amines such as, for example, 1,4-diazabicyclo[2.2.2]octane, diazabicyclononane, diazabicycloundecane, 1,1,3,3-tetramethylguanidine, 1,3,4,6,7,8-hexahydro-1-methyl-2H-pyrimido(1,2-a)pyrimidine.

Preference is given to dibutyltin dilaurate, butyltin trisoctoate, dimethylbis[(1-oxoneodecyl)oxy]stannane, dimethyltin dicarboxylate, 1,4-diazabicyclo[2.2.2]octane, diazabicyclononane, diazabicycloundecane, 1,1,3,3-tetramethylguanidine, 1,3,4,6,7,8-hexahydro-1-methyl-2H-pyrimido(1,2-a)pyrimidine.

The photopolymer layer may also contain further, auxiliary or added-substance chemistries. Solvents, plasticizers, flow control agents or adhesion promoters may be concerned here for example. The concurrent use of two or more added-substance chemistries of one type or of different types may also be advantageous here.

The photopolymer layer is obtainable by applying the photopolymer atop the substrate layer using a reel-type coating rig for example.

This is possible by combining various process steps wherein conventional forced metering pumps, vacuum devolatilizers, plate filters, static mixers, slot dies or various blade coating systems, single-reel unwinders, air dryers, dry lamination means and a single-reel winding means can be used. Specifically coating means including, for example, slot dies and blade systems are suitable for the application of liquid photopolymers atop substrate layers and are notable for a high level of accuracy in the thickness of the applied layer.

The constituents of the photopolymer may be sent as two separate components to a coating rig, mixed there and then applied atop the substrate layer. This is advantageous in particular when the matrix polymers are polyurethanes which, as described above, are obtainable by reacting at least one polyisocyanate component a) and at least one isocyanate-reactive component b). In this case, the first component may contain a polyisocyanate component a) and the second component an isocyanate-reactive component b). Further constituents of the photopolymer such as, for example, writing monomers, photoinitiators, free-radical stabilizers, fluorourethanes, solvents and additives may then be present not only wholly but also respectively in parts in the first component or the second component. When the photoinitiator system comprises at least one dye and a co-initiator aligned thereto, it may also be advantageous for the dye and the co-initiator to be present in one of the two components.

In a further preferred embodiment of the layered setup according to the present invention, the substrate layer has a minimum transmission ≧70% in the wavelength range from 410 to 780 nm. The transmission of a substrate layer is determined in a UV-VIS spectrometer in transmission geometry as per DIN 5036 in the spectral range from 410 to 780 nm according to wavelength. The minimum transmission is defined as the lowest transmission value determined therein according to wavelength. In a further preferred embodiment, the substrate layer has a minimum transmission of ≧75% and more preferably of ≧80%.

In a further preferred embodiment, the substrate layer has an essentially elastic strain of not more than 0.2% at a substrate width of one metre in response to a tensile force of at least 80 newtons, preferably of at least 110 newtons and more preferably of at least 140 newtons. Elastic strain is determined in an EN ISO 527-1 tensile test.

The substrate layer is constructable in polycarbonate, polyester, polyethylene, polypropylene, cellulose acetate, cellulose nitrate, cycloolefin polymer, polystyrene, styrene-acrylate copolymer, polysulphone, cellulose triacetate, polyamide, polymethyl methacrylate, polyvinyl chloride, copolymers of styrene with alkyl (meth)acrylates/ethylene/propylene, polyvinyl butyral, polydicyclopentadiene for example. However, substrate layers in polycarbonates (e.g. polycarbonates of bisphenol A, bisphenol C), amorphous and semicrystalline polyamides, amorphous and semicrystalline polyesters and also cellulose triacetates are particularly advantageous.

There may be an anti-adherent, antistatic, hydrophobized or hydrophilized finish on either side of the substrate layer or both. Any modifications on the side facing the photopolymer layer may be designed to promote non-destructive removal of the photopolymer layer from the substrate layer. Any modification on the substrate layer side which faces away from the photopolymer layer may be designed to ensure that the layered assembly of the present invention complies with specific mechanical requirements as apply, for example, to processing in reel-type laminators, in particular in the reel-to-reel process.

In a further preferred embodiment, the magnitude of the difference between the refractive index of the substrate layer (measured as per DIN EN ISO 489 at 589.3 am) and the refractive index of the photopolymer layer (quantifyied by fitting the spectral course of n to the visual transmission and reflection spectrum and reported for 589.3 nm) is ≦0.075, preferably ≦0.065 and more preferably ≦0.050. Particularly in specific optical setups such as edge-lit holograms and waveguiding holograms it is particularly advantageous to minimize the magnitude of the difference between the refractive indices of substrate layer and photopolymer layer.

In a likewise preferred embodiment, the substrate layer and the photopolymer layer are bonded to each other uniformly.

The substrate layer is from 10 to 250 m, preferably from 20 to 180 μm and more preferably from 35 to 150 μm in thickness and/or the photopolymer layer is from 0.5 to 200 μm and preferably from 1 to 100 μm in thickness.

In a further preferred embodiment of the layered setup according to the present invention, the photopolymer layer contains at least one exposed hologram.

More particularly, the hologram may be a reflection, transmission, in-line, off-axis, full-aperture transfer, white light transmission, Denisyuk, off-axis reflection or edge-lit hologram, or else a holographic stereogram, preferably a reflection, transmission or edge-lit hologram.

Possible optical functions of the holograms correspond to the optical functions of light elements such as lenses, mirrors, deflecting mirrors, filters, diffuser lenses, directed diffusion elements, directed holographic diffusers, diffractive elements, light guides, waveguides, coupling-in/out elements, projection lenses and/or masks. In addition, a plurality of such optical functions can be combined in such a hologram, for example such that the light is deflected in a different direction according to the incidence of light. For example, it is possible with such setups to build autostereoscopic or holographic electronic displays which allow a stereoscopic or holographic visual impression to be experienced without further aids, for example polarizer or shutter glasses. It is further possible to realize automotive head-up displays or head-mounted displays. It is likewise possible to use the layered setups of the present invention in correcting or sunglasses.

These optical elements frequently have a specific frequency selectivity according to how the holograms have been exposed and the dimensions of the hologram. This is important especially when monochromatic light sources such as LEDs or laser light are used. For instance, one hologram is required per complementary colour (RGB), in order to deflect light in a frequency-selective manner and at the same time to enable full-colour displays. Therefore, there are certain display setups where two or more holograms have to be exposed inside each other into the photopolymer layer.

In addition, by means of the layered setups of the present invention, it is also possible to produce holographic images or representations, for example for personal portraits, biometric representations in security documents, or generally of images or image structures for advertising, security labels, brand protection, branding, labels, design elements, decorations, illustrations, collectable cards, images and the like, and also images which can represent digital data, including in combination with the products detailed above. Holographic images can have the impression of a three-dimensional image, but they may also represent image sequences, short films or a number of different objects according to the angle from which and the light source with which (including moving light sources) etc. they are illuminated. Because of this variety of possible designs, holograms, especially volume holograms, constitute an attractive technical solution for the abovementioned application. It is also possible to use such holograms for storage of digital data, using a wide variety of different exposure methods (shift, spatial or angular multiplexing).

The invention likewise provides an optical display comprising a layered setup according to the present invention.

Examples of such optical displays are imaging displays based on liquid crystals, organic light-emitting diodes (OLEDs), LED display panels, microelectromechanical systems (MEMS) based on diffractive light selection, electrowetting displays (E-ink) and plasma display screens. Optical displays of this kind may be autostereoscopic and/or holographic displays, transmittive and reflective projection screens, displays with switchable restricted emission characteristics for privacy filters and bidirectional multiuser screens, virtual displays, head-up displays, head-mounted displays, illumination symbols, warning lamps, signal lamps, floodlights and display panels.

In addition, it is also possible to use a layered setup of the present invention in the manufacture of security documents such as, for example, chip cards, identity documents, 3D pictures, product protection labels, tags, banknotes or holographically optical elements particularly for optical displays.

The invention will now be more particularly elucidated by means of examples.

### ELUCIDATION OF FIGURES

FIG. 1: FIG. 2 shows the geometry of a holographic media tester (HMT) at λ=532 nm (DPSS laser): M=mirror, S=shutter, SF=spatial filter, CL=collimator lens, λ/2=λ/2 plate, PBS=polarization-sensitive beam splitter, D=detector, I=iris diaphragm, α0=−22.3°, β0=22.3° are the angles of incidence of the coherent beams measured outside the sample (the medium). RD=reference direction of turntable.

FIG. 2: shows the graphical evaluation of the retardation measurement on substrate 2 with the retardation distribution being mapped onto the 199 mm×149 mm area of measurement

FIG. 3: shows the graphical evaluation of the retardation measurement on substrate 3 with the retardation distribution being mapped onto the 199 mm×149 mm area of measurement

FIG. 4: shows a schematic setup for a continuous film-coating rig used (as reel-to-reel process)

FIG. 5: shows the measured and Kogelnik-fitted Bragg curve for Inventive Example 1

### METHODS OF MEASUREMENT

### Isocyanate Content

Reported NCO values (isocyanate contents) were quantified to DIN EN ISO 11909. The full conversion of NCO groups, i.e. the absence thereof, in a reaction mixture was detected by IR spectroscopy. Thus, complete conversion was assumed when no NCO band (2261 cm⁻¹) was visible in the IR spectrum of the reaction mixture.

### Solids Content

An unpainted tin can lid and a paperclip were used to ascertain the tare weight. Then about 1 g of the sample to be analysed was weighed out and then distributed homogeneously in the tin can lid with the suitably bent paperclip. The paperclip remained in the sample for the measurement. The starting weight was determined, then the assembly was heated in a laboratory oven at 125° C. for 1 hour, and then the final weight was quantified. The solids content was quantified by the following equation: Final weight [g]*100/starting weight [g]=% by weight of solids.

### Quantification of Refractive Index:

For the solid substrate, the refractive index was measured at room temperature at a wavelength of 589.3 nm by obtaining the refractive index n from the transmission and reflection spectra as a function of the wavelength of the sample. The transmission and reflection spectrum of this layered setup was measured with a CD-Measurement System ETA-RT spectrometer from STEAG ETA-Optik, and then the spectral profile of n was fitted to the measured transmission and reflection spectra. This was accomplished using the internal software of the spectrometer.

The refractive index was measured for the photopolymers at 589.3 nm using a Schmidt & Haensch DSR Lambda refractometer at 23° C. in accordance with DIN EN ISO 489 “Plastics—Determination of refractive index” after bleaching with light.

### Measurement of the Holographic Properties DE and an by Means of Twin Beam Interference in Transmission Arrangement

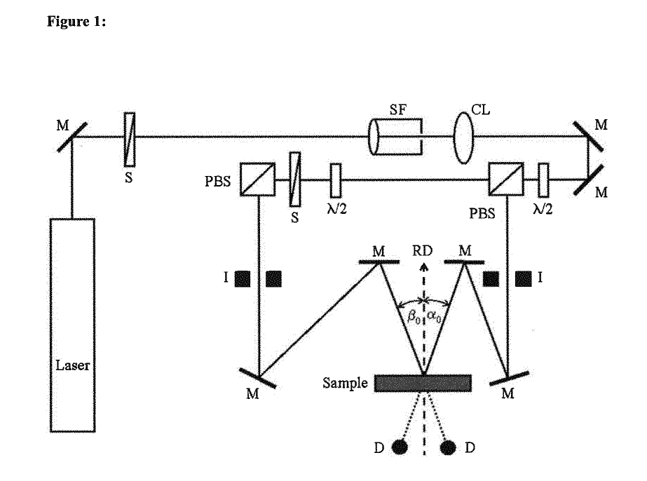

The holographic properties were tested using a measuring arrangement as per FIG. 1 as follows:

The beam of a DPSS laser (emission wavelength 532 nm) was converted to a parallel homogeneous beam with the aid of the spatial filter (SF) and together with the collimation lens (CL). The final cross sections of the signal and reference beam were fixed by the iris diaphragms (I). The diameter of the iris diaphragm opening was 0.4 cm. The polarization-dependent beam splitters (PBS) split the laser beam into two coherent beams of identical polarization. By means of the λ/2 plates, the power of the reference beam was set to 0.1 mW and the power of the signal beam to 0.1 mW. The powers were determined using the semiconductor detectors (D) with the sample removed. The angle of incidence (α₀) of the reference beam is −22.3°; the angle of incidence (β₀) of the signal beam is 22.3°. The angles are measured proceeding from the sample normal to the beam direction. According to FIG. 1, therefore, α₀ has a negative sign and β₀ a positive sign. At the location of the sample (medium), the interference field of the two overlapping beams produced a pattern of light and dark strips parallel to the angle bisectors of the two beams incident on the sample (transmission hologram). The strip spacing Λ, also called grating period, in the medium is ˜700 nm (the refractive index of the medium assumed to be ˜1.504).

FIG. 1 shows the holographic test setup with which the diffraction efficiency (DE) of the media was measured.

Holograms were written into the photopolymer layer in the following manner.
Both shutters (S) are opened for the exposure time t.
Thereafter, with the shutters (S) closed, the medium is allowed 5 minutes for the diffusion of the as yet unpolymerized writing monomers.

The written holograms were then read out in the following manner. The shutter of the signal beam remained closed. The shutter of the reference beam was opened. The iris diaphragm of the reference beam was closed to a diameter of <1 mm. This ensured that the beam was always completely within the previously recorded hologram for all angles of rotation (Ω) of the medium. The turntable, under computer control, swept over the angle range from Ωₘᵢₙ to Ωₘₐₓ with an angle step width of 0.05°. Ω was measured from the sample normal to the reference direction of the turntable. The reference direction (Ω=0) of the turntable was obtained when the angles of incidence of the reference beam and of the signal beam have the same absolute value on recording of the hologram, i.e. α₀=−22.3° and β₀=22.3°. In general, the following was true of the interference field in the course of recording a symmetric transmission hologram (α₀=−β₀):

α₀=θ₀

θ₀ was the semiangle in the laboratory system outside the medium. Thus, in this case, θ₀=−22.3°. At each setting for the angle of rotation Ω, the powers of the beam transmitted in the zeroth order were measured by means of the corresponding detector D, and the powers of the beam diffracted in the first order by means of the detector D. The diffraction efficiency was calculated at each setting of angle Ω as the quotient of:

$$η = \frac{{P}_{D}}{{P}_{D} + {P}_{T}}$$

P_{D} is the power in the detector for the diffracted beam and P_{T} is the power in the detector for the transmitted beam.

By means of the process described above, the Bragg curve, which describes the diffraction efficiency η as a function of the angle of rotation Ω, for the recorded hologram, was measured and saved on a computer. In addition, the intensity transmitted into the zeroth order was also recorded against the angle of rotation Ω and saved on a computer.

The central diffraction efficiency (DE=η₀) of the hologram was determined at Ω=0.

The refractive index contrast Δn and the thickness d of the photopolymer layer were now fitted to the measured Bragg curve by means of coupled wave theory (see: H. Kogelnik, The Bell System Technical Journal, Volume 48, November 1969, Number 9 page 2909-page 2947). The evaluation process is described hereinafter:

For the Bragg curve η(Ω) of a transmission hologram, according to Kogelnik:

$$η = \frac{{sin}^{3} ( \sqrt{{v}^{2} + {ξ}^{2}} )}{1 + \frac{{ξ}^{2}}{{v}^{2}}}$$

$$with \text{:}$$

$$v = \frac{π \cdot Δ n \cdot d}{λ \cdot \sqrt{\vert {c}_{r} \cdot {c}_{r} \vert}}$$

$$ξ = - \frac{d}{2 \cdot {c}_{s}} \cdot DP$$

$${c}_{s} = cos ( ϑ )$$

$${c}_{r} = cos ( ϑ )$$

$$DP = \frac{π}{Λ} \cdot ( - 2 \cdot sin ( ϑ ) - \frac{λ}{n \cdot Λ} )$$

$$Λ = - \frac{λ}{2 \cdot n \cdot sin ( α )}$$

The following holds for the reading out (“reconstruction”) of the hologram similarly to the above explanation:

Θ₀=θ₀+Ω

sin(Θ₀)=n·sin(Θ)

Under the Bragg condition, the “dephasing” DP=0. And it follows correspondingly that:

α₀=θ₀

sin(α₀)=n·sin(α)

v is the grating intensity and ξ is the detuning parameter of the refractive index grating written. n is the average refractive index of the photopolymer and was set equal to 1.504. λ is the wavelength of the laser light in vacuo.

The central diffraction efficiency (DE=η₀)), when ξ=0, is then calculated to be:

$$DE = {sin}^{2} ( v ) = {sin}^{2} ( \frac{π \cdot Δ n \cdot d}{λ \cdot cos ( α )} )$$

The measured data for the diffraction efficiency and the theoretical Bragg curve are plotted against the angle of rotation Ω, as shown in FIG. 5.

Since DE is known, the shape of the theoretical Bragg curve, according to Kogelnik, is determined only by the thickness d of the photopolymer layer. Δn is corrected via DE for a given thickness d such that measurement and theory for DE are always in agreement. d is thus adjusted until the angle positions of the first secondary minima and the heights of the first secondary maxima of the theoretical Bragg curve correspond to the angle positions of the first secondary minima and the heights of the first secondary maxima of the measured Bragg curve.

FIG. 5 shows the plotted Bragg curve η according to the coupled wave theory (solid line) and a plot of the measured diffraction efficiency (circles) versus the rotation angle Ω.

For a formulation, this procedure was repeated, possibly several times, for different exposure times t on different media, in order to find the mean energy dose of the incident laser beam in the course of recording of the hologram at which Δn reaches the saturation value. The mean energy dose E is calculated as follows from the powers of the two component beams assigned to the angles α₀ and β₀ (reference beam where Pᵣ=0.01 mW and signal beam where Pₛ32 0.01 mW), the exposure time t and the diameter of the iris diaphragm (0.4 cm):

$$E ( mJ / {cm}^{2} ) = \frac{2 \cdot [ {P}_{r} + {P}_{s} ] \cdot t ( s )}{π \cdot {0.4}^{2} {cm}^{2}}$$

WO2013053791A1, page 31 ff., is referenced here for the measurement in reflection mode.

### Measurement of Retardation

An M3 Strainmatic from Ilis GmbH, D91052-Erlangen (Germany) was used to measure the substrate layers to determine their optical retardation. The measuring instrument used is an imaging polarimeter system possessing an optical setup consisting of light source, polarizer, sample, lambda quarter plate, analyser and detector. The (areal) light source used was monochromatic light at lambda=587 nm, which was linearly polarized by the polarizer. The sample specimen then transforms the linearly polarized light into elliptically polarized light. The lambda quarter plate then transformed the light subsequently back into linearly polarized light whose polarization plane was rotated by the sample by a certain angle α relative to the original direction of polarization. This angle was then determined using the analyser and the positionally resolved (CCD) detector. The retardation R was computed via the relationship

$$R = \frac{a \cdot λ}{180 °}$$

in nanometres [nm]. Owing to the measurement principle, the retardation was only determined for the preferential direction of the linearly polarized light and the measurement axis arrangement. The polarizer was therefore subsequently rotated in 90° steps and the measurement repeated each time. The evaluative software (Version v2013.1.27.126) allowed for this geometric dependence to provide a depiction of the optical retardation including a statistical evaluation for a CCD detector distance of 465.0 mm and the measured size of 199.0 mm×149.2 mm for the image.

### Determination of Optical Quality

The phase profile of two interfering planar waves after passage through a layered setup was visualized in an interference experiment (e.g. a Fizeau or else Tyman-Green interferometer) and recorded using a CCD camera. Data points were obtained across the measured area which characterize the phase change of the lightwave following passage through the layered setup and the number of which corresponds to the pixel number of the camera. These changes were statistically evaluated versus a blank measurement without sample to represent the ideal image of a defect-free arrangement. Characterizing parameters in common use are the peak-to-valley value, which indicates the maximum difference between the highest point and the lowest point, and also the RMS value, which is defined as the root of the square mean of the deviation of the measured phase distribution from the ideal distribution. Both these characterizing parameters can be determined for the entire set of data points and also defined subsets. Where the subset is a straight line, the spatial derivative of the RMS can be formed as a measure for the maximum slope and the degree of phase changeability along a direction. This presentation of the RMS—that is, as a derivative along a direction—is of particular relevance for holographically optical elements.

The Strehl value S (the Strehl ratio) indicates one quality of the image-formation quality of an optical system. As defined in DIN ISO 10110-5 as well as elsewhere, the Strehl value describes a light intensity ratio for the experimentally determined intensity of a point image in relation to that of an identical image-forming system assumed to be defect-free (i.e. aberration-free). A Strehl value is easy to determine for an interferometric setup by the picture of a measured phase distribution being computed via a simple Fourier transformation and set into proportion relative to the ideal of a planar wave. The phase shift range length P, then, is the key parameter resulting from the quotient formed by dividing the maximum slope of the RMS value along two orthogonal directions into the Strehl value. The result is accordingly one parameter to combine a measure of imaging quality (Strehl) with the deviation from the ideal shape of a plane phase surface. A phase shift range length P of at least 0.8 cm/wavelength is required for a layered setup in accordance with the present invention, preferably at least a phase shift range length P of 1.0 cm/wavelength, more preferably of at least 1.2 cm/wavelength. The interferometer measurement wavelength used was 633 nm.

The optical quality of the exposed layered setup obtained was determined using a GPI-xpD Fizeau interferometer from Zygo, Middlefield, Conn. (USA). The instrument has a laser unit (lambda=633 nm) whose beam was expanded and collimated to the size of two optically planar circular glass flats 15 cm in diameter. The expanded laser beam passed through the two mutually parallel glass flats and the retroactive interference was recorded by a CCD camera (1024×1024 pixels). A reference measurement was carried out first, against an air-filled cavity (=the region between the glass flats). This should give a phase shift range length P>10. The phase shift range length P computes from Q=Strehl/RMS (RMS=square mean of variance of n·d, where n=refractive index of the material and d=layer thickness). If this was not achieved, the alignment of the glass flats relative to each other was adjusted such that they were parallel to each other. A corresponding check was done by visual inspection with the CCD camera at the control monitor until interference fringes were no longer visible in the area of measurement.

The foil sample to be measured was adhered to a metal frame 10 cm×10 cm in size and freely positioned between the glass flats. The measurement window was applied using software (Metropro V8.3.5, from Zygo) in the form of a measurement mask. The measurement was started and CCD camera images were automatically recorded by the software. The measurement takes 1-15 seconds under automatic control, depending on the planarity of the measured specimen. The following setting parameters are chosen: resolution +/−1 wavelength, distance of evaluation was effected over 10 cm, vertical deflections are calibrated to the maximum extension. The software computed the phase shift range length P, Strehl and RMS from the spatially resolved measured image obtained.

### Chemicals and Substrates:

### Preparation of Polyol 1:

A 1 l flask was initially charged with 0.18 g of tin octoate, 374.8 g of ε-caprolactone and 374.8 g of a difunctional polytetrahydrofuran polyether polyol (equivalent weight 500 g/mol OH), which were heated to 120° C. and kept at this temperature until the solids content (proportion of nonvolatile constituents) was 99.5% by weight or higher. Subsequently, the mixture was cooled and the product was obtained as a waxy solid.

### Preparation of urethane acrylate 1 (writing monomer): Phosphorothoyltris (oxybenzene-4,1-diylcarbamoyloxyethane-2,1-diyl) trisacrylate

A 500 mL round-bottom flask was initially charged with 0.1 g of 2,6-di-tert-butyl-4-methylphenol, 0.05 g of dibutyltin dilaurate and 213.07 g of a 27% solution of tris(p-isocyanatophenyl) thiophosphate in ethyl acetate (Desmodur® RFE, product from Bayer MaterialScience AG, Leverkusen, Germany), which were heated to 60° C. Subsequently, 42.37 g of 2-hydroxyethyl acrylate were added dropwise and the mixture was still kept at 60° C. until the isocyanate content had fallen below 0.1%. This was followed by cooling and complete removal of the ethyl acetate in vacuo. The product was obtained as a partly crystalline solid.

### Preparation of urethane acrylate 2 (writing monomer): 2-({[3-(Methylsulphanyl)phenyl]carbamoyl}oxy)ethyl prop-2-enoate

A 100 ml round-bottom flask was initially charged with 0.02 g of 2,6-di-tert-butyl-4-methylphenol, 0.01 g of Desmorapid Z, 11.7 g of 3-(methylthio)phenyl isocyanate [28479-1-8], and the mixture was heated to 60° C. Subsequently, 8.2 g of 2-hydroxyethyl acrylate were added dropwise and the mixture was still kept at 60° C. until the isocyanate content had fallen below 0.1%. This was followed by cooling. The product was obtained as a colourless liquid.

### Preparation of additive 1 bis(2,2,3,3,4,4,5,5,6,6,7,7-dodecafluoroheptyl)(2,2,4-trimethylhexane-1,6-diyl) biscarbamate

A 50 ml round-bottom flask was initially charged with 0.02 g of Desmorapid Z and 3.6 g of 2,4,4-trimethylhexane 1,6-diisocyanate (TMDI), and the mixture was heated to 60° C. Subsequently, 11.9 g of 2,2,3,3,4,4,5,5,6,6,7,7-dodecafluoroheptan-1-ol were added dropwise and the mixture was still kept at 60° C. until the isocyanate content had fallen below 0.1%. This was followed by cooling. The product was obtained as a colourless oil.

### Borate (Photoinitiator):

The borate was prepared as described in Example 1 of European application EP 13189138.4. A 51.9% solution of benzyldimethylhexadecylammonium borate was obtained.

### Dye 1:

The preparation of the dye is described in Example 1 of WO 2012 062655.

### Dye 2:

The preparation of the dye is described in Example 9 of WO 2012 062655.

### Dye 3:

The preparation of the dye is described in Example 15 of WO 2012 062655.

### Dye 4:

The preparation of the dye is described in Example 14 of WO 2012 062655.

### Substrate 1:

Transphan OG622 GL is a 60 μm thick polyamide foil from LOFO high Tech Film GMBH, DE-79576 Well am Rhein (Germany), its refractive index nD was found to be 1.547.

### Substrate 2:

Tacphan 915-GL is a 50 μm thick triacetate foil from LOFO high Tech Film GMBH, DE79576 Well am Rhein (Germany), its refractive index nD was found to be 1.475.

### Substrate 3:

Makrofol DE 1-1 is a 125 μm thick polycarbonate foil from Bayer MaterialScience AG, DE51368 Leverkusen (Germany), its refractive index nD was found to be 1.596.

### Substrate 4:

Hostaphan RNK 36 is a 36 μm thick polyethylene terephthalate foil from Mitsubishi Polyester Film GmbH, D-65203 Wiesbaden (Germany), its refractive index nD was found to be 1.668.

### Substrate 5:

Pokalon Pokalon OG 641 GL, a 75 μm thick polycarbonate foil from LOFO high Tech Film GMBH, DE-79576 Weil am Rhein (Germany), its refractive index nD was found to be 1.576.

### Substrate 6:

Pokalon OG 642 GL, a 80 μm thick polycarbonate foil from LOFO high Tech Film GMBH, DE-79576 Weil am Rhein (Germany), its refractive index nD was found to be 1.576.

### Substrate 7:

Tacphan I 800 GL, a 40 μm thick triacetate foil from LOFO high Tech Film GMBH, DE79576 Weil am Rhein (Germany), its refractive index nD was found to be 1.485.
Desmodur® N 3900 product from Bayer MaterialScience AG, Leverkusen, DE, hexane diisocyanate-based polyisocyanate, proportion of iminooxadiazinedione at least 30%, NCO content: 23.5%.
Trimethylhexamethylene diisocyanate [28679-16-5]—ABCR GmbH & Co KG, Karlsruhe, Germany
1H,1H-7H-Perfluoroheptan-1-ol [335-99-9]—ABCR GmbH & Co KG, Karlsruhe, Germany
Desmorapid Z Dibutyltin Dilaurate [77-58-7], product from Bayer MaterialScience AG, Leverkusen, Germany.
Fomrez UL 28 Urethanization catalyst, commercial product of Momentive Performance Chemicals, Wilton, Conn., USA.
Sodium bis(2-ethylhexyl)sulphosuccinate [45297-26-5] is available from Aldrich Chemie, Steinheim.
4-Chlorophenylmagnesium bromide [873-77-8] is available as 0.9 M solution in THF/toluene from Aldrich Chemie, Steinheim.
Tetrabutylammonium bromide [1643-19-2] is available from ABCR GmbH & CO. KG, Karlsruhe.
BYK® 310 silicone-based surface additive from BYK-Chemie GmbH, Wesel, 25% solution in xylene
Ethyl acetate [141-78-6] solvent

### Determination of Retardation of Substrates

Table 1 shows the results for the retardation measurement on substrates 1-7. Substrates 1 and 2 exhibit low retardation values and are suitable for layered setups according to the present invention. Substrates 3 and 4, by contrast, have excessively high retardation values and accordingly are not used for layered setups according to the present invention.

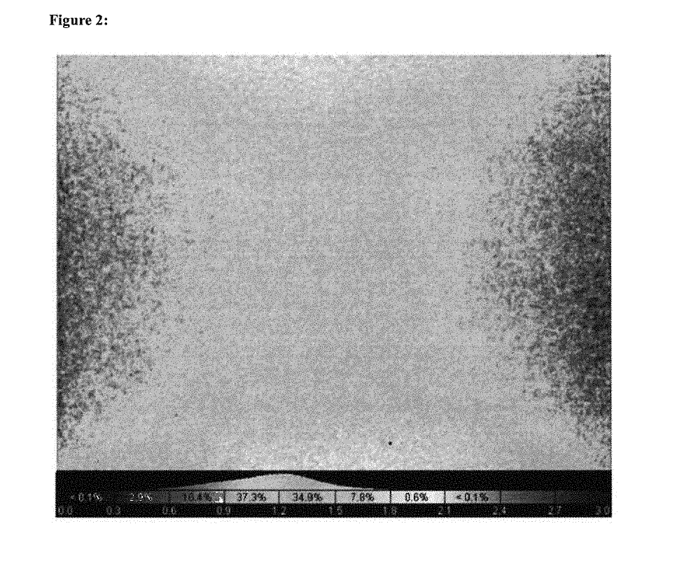

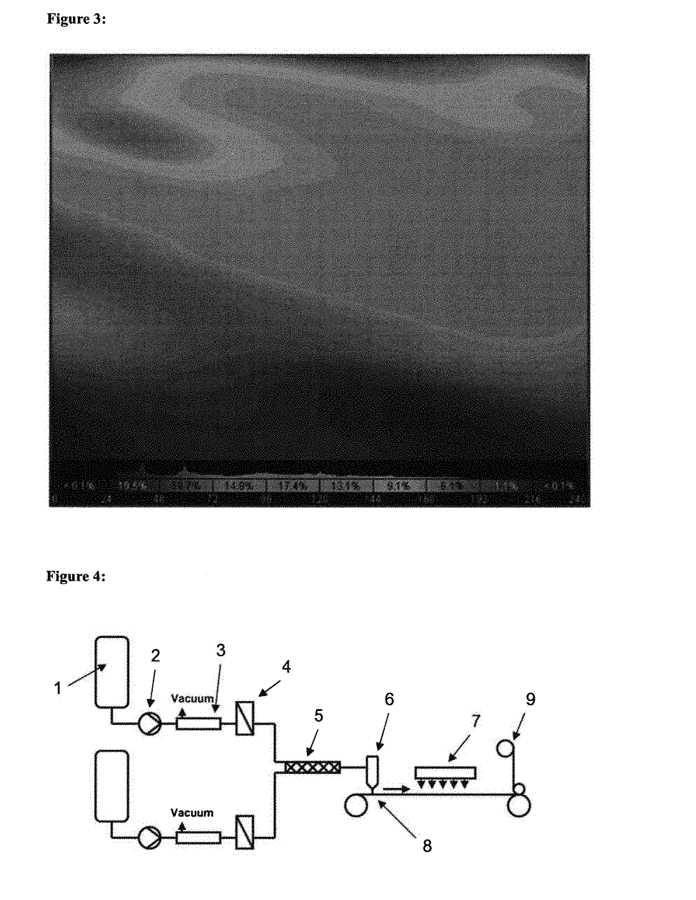

TABLE 1
Maximum and average retardation of substrates 1-7 and its
standard deviation in [nm]; see also FIG. 2 and FIG. 3, which
show the graphical evaluation for substrates 2 and 3 respectively.

| | Maximum | | |
|---|---|---|---|
| | retardation | Average retardation | Standard deviation |
| Substrate 1 | 30.4 nm | 20.0 nm | 3.5 nm |
| Substrate 2 | 2.3 nm | 1.1 nm | 0.3 nm |
| Substrate 3 | 220.4 nm | 94.8 nm | 44.8 nm |
| Substrate 4 | 2762.0 nm | 740.6 nm | 101.4 nm |
| Substrate 5 | 12.7 nm | 7.7 nm | 1.6 nm |
| Substrate 6 | 12.2 nm | 7.8 nm | 1.0 nm |
| Substrate 7 | 2.8 nm | 0.5 nm | 0.2 nm |

Production of Layered Setups on a Foil Coating Rig

The continuous production of layered setups will now be described.

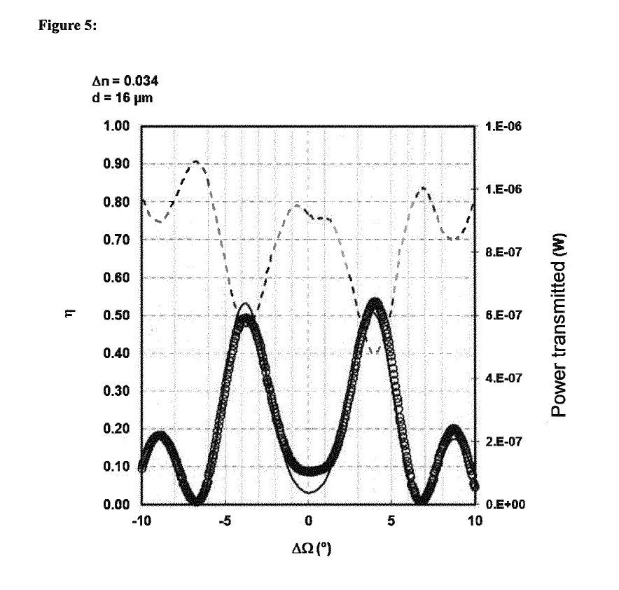

FIG. 4 shows the schematic setup of the coating rig used. In said figure, the individual component parts have the following reference signs:

| | |
|---|---|
| 1 | reservoir vessel |
| 2 | metering unit |
| 3 | vacuum degassing unit |
| 4 | filter |
| 5 | static mixer |
| 6 | coating unit |
| 7 | circulating air dryer |
| 8 | substrate layer |
| 9 | covering layer |

To prepare photopolymer formulation 1, 38.6 parts of polyol 1, 18.1 parts each of urethane acrylate 1 and of urethane acrylate 2, 25 parts of additive 1, 1 part of BYK 310, 0.22 part of dye 1 were prepared as ethyl acetate solution (concentration see table 2). This mixture was introduced into one of the two reservoir vessels 1 of the coating rig. The second reservoir vessel 1 was charged with 7.32 parts of Desmodur N3900 and 3.22 parts of borate. A mixture of sterically hindered amine and a phenol was used as stabilizers, 0.075 part of Fomrez UL 28 was used as urethanization catalyst. Photopolymer 2 differs from photopolymer 1 in its amount of urethane acrylate 1 (7.5% on solids), urethane acrylate 2 (7.5% on solids), additive 1 (10% on solids) and by replacing dye 1 with a mixture of dyes 2, 3 and 4.

Each of the two components were then conveyed by the metering units 2 to the vacuum degassing device 3, and degassed. From here, they were then each passed through the filters 4 into the static mixer 5, in which the components were mixed. The liquid material obtained was then sent in the dark to the coating unit 6.

The coating unit 6 in the present case was a slot die known to a person skilled in the art. Using coating unit 6, the photopolymer formulation was applied to the particular substrate layer (see also tables 3 and 4) at a processing temperature of 20° C. and dried in circulating air dryer 7. This gave a layered setup in the form of a coated film which was then covered with a 40 μm polyethylene foil as covering layer 9 and wound up. Table 2 shows the individual coating conditions,

TABLE 2
Preparation parameters

| | Solvent | Thickness of | | Dwell time in |
|---|---|---|---|---|
| | content | photopolymer | Dryer temperature | dryer |
| Example | (wt %) | layer (μm) | (° C.) | (min) |
| 1 | 50 | 16 | 100 | 3.3 |
| 2 | 50 | 16 | 100 | 4.3 |
| 3 | 50 | 16 | 100 | 3.3 |
| 4 | 60 | 10 | 100 | 3.3 |
| 5 | 60 | 10 | 100 | 3.3 |

A refractive index nD=1.491 was determined for photopolymer 1 and a refractive index nD=1.505 for photopolymer 2.

Table 3 describes three different layered setups which are based on photopolymer 1 but differ in having three different substrates 2, 3 and 4. The three layered setups all exhibit good holographic properties (in the form of index modulation Δn). The average retardation of substrates 3 and 4 is distinctly above 60 nm, their phase shift range length P is below the required 0.8 cm/wavelength (Wv=wavelength). The layered setups of Examples 2 and 3 are accordingly not in accordance with the present invention. Only the Inventive Example 1 layered setup, comprising substrate 2 with an average retardation <60 nm, exhibits a good phase shift range length P of 1.20 cm/wavelength.

TABLE 3
Layered setup properties and optical properties

| | Inventive | Noninventive | Noninventive |
|---|---|---|---|
| | Example 1 | Example 2 | Example 3 |
| Substrate | Substrate 2 | Substrate 3 | Substrate 4 |
| Refractive index of | 1.475 | 1.596 | 1.668 |
| substrate | | | |
| Photopolymer | 1 | 1 | 1 |
| Refractive index of | 1.491 | 1.491 | 1.491 |
| photopolymer | | | |
| Magnitude of difference | 0.016 | 0.105 | 0.177 |
| in refractive | | | |
| indices | | | |
| Average retardation | 1.1 nm | 94.8 nm | 740.6 nm |
| of substrate layer | | | |

Layered setup properties

| | | | |
|---|---|---|---|
| Strehl | 0.69 | 0.63 | 0.47 |
| RMS value | 0.59 Wv/cm | 0.99 Wv/cm | 1.25 Wv/cm |
| Phase shift range | 1.20 cm/Wv | 0.64 cm/Wv | 0.37 cm/Wv |
| length P | | | |
| Holographic performance | 0.034@16 | 0.031@16 | 0.031@16 |
| Δn | mJ/cm2 | mJ/cm2 | mJ/cm2 |
| | (532 nm, | (532 nm, | (532 nm, |
| | transmission) | reflection) | reflection) |

Table 4 shows two inventive examples with sufficiently low average retardation and hence very good phase shift range length P>1.20 cm/wavelength. The inventive examples all also exhibit good holographic properties. [Wv=wavelength]

TABLE 4
Layered setup properties and optical properties

| | Inventive Example 4 | Inventive Example 5 |
|---|---|---|
| Substrate | Substrate 1 | Substrate 2 |
| Refractive index of | 1.547 | 1.475 |
| substrate | | |
| Photopolymer | 2 | 2 |
| Refractive index of | 1.505 | 1.505 |
| photopolymer | | |
| Magnitude of difference | 0.042 | 0.030 |
| between refractive | | |
| indices | | |
| Average retardation | 20.4 nm | 1.1 nm |

Layered setup properties

| | | |
|---|---|---|
| Strehl | 0.79 | 0.87 |
| RMS value | 0.55 Wv/cm | 0.40 Wv/cm |
| Phase shift range | 1.44 cm/Wv | 2.19 cm/Wv |
| length P | | |
| Holographic performance | 0.013@16 mJ/cm2 | 0.011@16 mJ/cm2 |
| Δn | (532 nm, transmission) | (532 nm, transmission) |

1.-16. (canceled)

17. A layered setup comprising a substrate layer and a photopolymer layer bonded thereto at least segmentally, wherein the substrate layer has an average retardation of ≦60 nm.

18. The layered setup according to claim 17, wherein the substrate layer has an average retardation of ≦40 nm.

19. The layered setup according to claim 17, wherein the average retardation of the substrate layer is quantified by an imaging polarimeter system comprising a monochromatic LED light source, a polarizer, a sample, a lambda quarter plate, an analyser and a detector, being used to measure the polarization plane rotation α in a positionally resolved manner and the quantified positionally resolved retardation R being computed by the formula R=α*λ/180°, where λ is the measuring frequency, and then being arithmetically averaged over all positionally resolved retardation values, wherein the LED light source has a narrow-banded emission spectrum having a full width at half maximum value <50 nm and also a maximum emission wavelength of λ=580 nm to 595 nm.

20. The layered setup according to claim 17, wherein the substrate layer has a maximum (positionally resolved) retardation of ≦200 nm.

21. The layered setup according to claim 17, wherein the photo-polymer layer comprises matrix polymers, writing monomers and a photoinitiator system.

22. The layered setup according to claim 21, wherein the matrix polymers comprise polyurethanes.

23. The layered setup according to claim 21, wherein the writing monomers comprise of one or more urethane (meth)acrylates.

24. The layered setup according to claim 21, wherein the photoinitiator system consists of a sensitizer that absorbs in the visible spectrum and of a co-initiator.

25. The layered setup according to claim 21, wherein the photo-polymer layer comprises fluorourethanes according to formula (II) 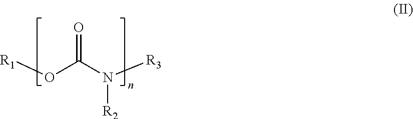
where n is ≧1 and ≦8 and R₁, R₂ and R₃ are each independently hydrogen or linear, branched, cyclic or heterocyclic unsubstituted or else optionally heteroatom-substituted organic moieties, wherein at least one of R₁, R₂ and R₃ is substituted with at least one fluorine atom and more preferably R₁ is an organic moiety having at least one fluorine atom.

26. The layered setup according to claim 17, wherein the substrate layer has a minimum transmission ≧70% in the wavelength range from 410 to 780 nm.

27. The layered setup according to claim 17, wherein the substrate layer has an essentially elastic strain of not more than 0.2% at a substrate width of one meter in response to a tensile force of at least 80 newtons.

28. The layered setup according to claim 17, wherein the magnitude of the difference in refractive index at 589.3 nm between the substrate layer and the photopolymer layer is ≦0.075, wherein refractive index is determined for the photopolymer as per DIN EN ISO 489 and for the substrates by fitting the spectral course of refractive index on the basis of the visual reflection and transmission spectra.

29. The layered setup according to claim 17, wherein the substrate layer and the photopolymer layer are bonded to each other uniformly.

30. The layered setup according to claim 17, wherein the substrate layer is from 10 to 250 μm in thickness and/or the photopolymer layer is from 0.3 to 200 μm in thickness.

31. The layered setup according to claim 17, wherein the photo-polymer layer contains at least one exposed hologram.

32. An optical display comprising a layered setup according to claim 17.
